(19) United States
(12) Patent Application Publication
(10) Pub. No.: US 2025/0253166 A1
(43) Pub. Date: Aug. 7, 2025

(54) SUBSTRATE PROCESSING APPARATUS AND SUBSTRATE PROCESSING METHOD

(71) Applicant: Tokyo Electron Limited, Tokyo (JP)

(72) Inventor: Yoshitomo SATO, Kumamoto (JP)

(21) Appl. No.: 18/855,160

(22) PCT Filed: Apr. 4, 2023
(86) PCT No.: PCT/JP2023/013963

§ 371 Date: Oct. 8, 2024

(30) Foreign Application Priority Data
Apr. 18, 2022 (JP) 2022-068333

(51) Int. Cl. H01L 21/67; H01L 21/02; H01L 21/311

(52) U.S. Cl. CPC H01L 21/67051; H01L 21/02087; H01L 21/31111; H01L 21/6708

(57) ABSTRACT

A substrate processing device removes the peripheral edge section of a film formed on an upper surface of a substrate. This substrate processing device comprises: a substrate rotating part which horizontally holds and rotates the substrate; a first nozzle which supplies, toward the substrate, a first processing fluid for hindering the removal of the film, from above the substrate held by the substrate rotating part; a second nozzle which supplies, toward the substrate, a second processing fluid for removing the film, from below the substrate held by the substrate rotating part; and a control unit which controls the rotation of the substrate, the supply of the first processing fluid, and the supply of the second processing fluid. The control unit, while the substrate is rotated at a first rotation speed by the substrate rotation part, supplies the first processing fluid by means of the first nozzle, and supplies the second processing fluid by means of the second nozzle, thereby performing control for removing the peripheral edge section of the film.

### TECHNICAL FIELD

The present invention relates to a substrate processing apparatus and a substrate processing method.

### BACKGROUND

A substrate processing apparatus described in Patent Document 1 removes the peripheral portion of a film formed on the upper surface of a substrate. The upper surface of the substrate has a horizontal surface and a bevel surface formed outside the horizontal surface. A chemical solution is supplied to the horizontal surface of the upper surface of the rotating substrate, and then flows outwards in the radial direction by a centrifugal force, thereby removing the peripheral portion of the film. On the upper surface of the substrate, a boundary is formed between a covered portion where the film remains, and an exposed portion from which the film is removed. The exposed portion is formed on the radial outside of the covered portion. The boundary between the covered portion and the exposed portion is present on the horizontal surface (see FIG. 11 in Patent Document 1).

### PRIOR ART DOCUMENT

### Patent Document

Patent Document 1: Japanese Patent Laid-Open Publication No. 2017-183498

### SUMMARY OF THE INVENTION

### Problem to be Solved

According to an aspect of the present disclosure, provided is a technology of reducing the width of an exposed portion of an upper surface of a substrate from the top view.

### Means to Solve the Problem

A substrate processing apparatus according to an aspect of the present disclosure removes a peripheral portion of a film formed on an upper surface of a substrate. The substrate processing apparatus includes: a substrate rotating unit that horizontally holds and rotates the substrate; a first nozzle that supplies a first processing liquid toward the substrate from above the substrate held by the substrate rotating unit, thereby inhibiting removal of the film; a second nozzle that supplies a second processing liquid toward the substrate from below the substrate held by the substrate rotating unit, thereby removing the film; and a control unit that controls rotation of the substrate, supply of the first processing liquid, and supply of the second processing liquid. The control unit controls the first nozzle and the second nozzle to supply the first processing liquid and the second processing liquid, respectively, while rotating the substrate by the substrate rotating unit at a first rotational speed, thereby removing the peripheral portion of the film.

### Effect of the Invention

According to an aspect of the present disclosure, it is possible to reduce the width of an exposed portion of an upper surface of a substrate from the top view.

### BRIEF DESCRIPTION OF THE DRAWINGS

FIG. 1 is a cross-sectional view illustrating a substrate processing apparatus according to one embodiment.

FIG. 2 is a cross-sectional view illustrating an example of a substrate before processing.

FIG. 3 is a cross-sectional view illustrating an example of a substrate after processing.

FIG. 4 is a cross-sectional view illustrating an example of a main part of the substrate processing apparatus.

FIG. 5 is a flowchart illustrating a substrate processing method according to one embodiment.

FIG. 6 is a view illustrating an example of a recipe for steps S101 to S104 in FIG. 5.

FIG. 7 is a cross-sectional view illustrating an example of step S101 in FIG. 5.

FIG. 8 is a cross-sectional view illustrating an example of step S102 in FIG. 5.

FIG. 9 is a cross-sectional view illustrating an example of step S103 in FIG. 5.

FIG. 10 is a view illustrating an example of the relationship between the presence or absence of supply of a first processing liquid, a first rotational speed, and a cut width.

FIG. 11 is a view illustrating an example of an imaging unit.

FIG. 12 is a view illustrating an example of an image captured by the imaging unit.

### DETAILED DESCRIPTION TO EXECUTE THE INVENTION

Hereinafter, an embodiment of the present disclosure will be described with reference to drawings. Also, in the drawings, the same or corresponding components may be denoted by the same reference numerals, and the descriptions thereof may be omitted. In the present specification, the X-axis direction, the Y-axis direction, and the Z-axis direction are mutually perpendicular directions. The X-axis direction and the Y-axis direction are horizontal directions, and the Z-axis direction is a vertical direction.

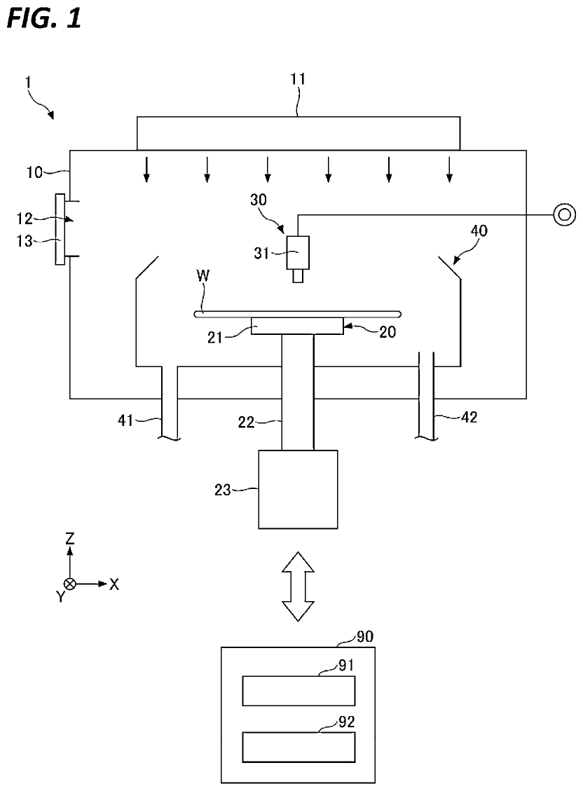

A substrate processing apparatus 1 according to one embodiment will be described with reference to FIG. 1. The substrate processing apparatus 1 processes a substrate W by supplying a processing liquid to the substrate W while rotating the substrate W. The substrate processing apparatus 1 includes, for example, a processing container 10, a substrate rotating unit 20, a processing liquid supply unit 30, a cup 40, and a control unit 90.

A fan filter unit (FFU) 11 is provided on the ceiling of the processing container 10. The FFU 11 forms a downflow inside the processing container 10. A gate 12, and a gate valve 13 that opens and closes the gate 12 are provided on the side wall of the processing container 10. The substrate W is carried into the processing container 10 through the gate 12 by a transport device (not illustrated), and is treated with a processing liquid within the processing container 10, and then, is carried out of the processing container 10 through the gate 12 by the transport device.

The substrate rotating unit 20 horizontally holds and rotates the substrate W. The substrate rotating unit 20 includes, for example, a holder 21, a rotation shaft 22, and a rotation driving unit 23. The holder 21 is provided inside the processing container 10, and horizontally holds the substrate W such that the center of the substrate W coincides with the rotation center line of the rotation shaft 22. The holder 21 sucks, for example, the center of the lower surface of the substrate W. The rotation driving unit 23 rotates the holder 21 around the vertical rotation shaft 22.

The processing liquid supply unit 30 supplies a processing liquid to the substrate W. The processing liquid supply unit 30 includes, for example, a nozzle 31. The nozzle 31 is connected to a supply source of the processing liquid. The nozzle 31 is provided inside the processing container 10, and ejects the processing liquid to the substrate W held by the holder 21. The nozzle 31 may be a two-fluid nozzle that mixes and ejects a liquid and a gas. The nozzle 31 is movable in the horizontal direction and the vertical direction.

The cup 40 surrounds the periphery of the substrate W held by the holder 21, and receives the processing liquid scattering from the periphery of the substrate W. The cup 40 does not rotate together with the rotation shaft 22 in the present embodiment, but may rotate together with the rotation shaft 22. A drain pipe 41 and an exhaust pipe 42 are provided at the bottom of the cup 40. The drain pipe 41 discharges the liquid accumulated inside the cup 40. The exhaust pipe 42 discharges the gas accumulated inside the cup 40.

The control unit 90 is, for example, a computer, and includes a central processing unit (CPU) 91, and a storage medium 92 such as a memory. The storage medium 92 stores programs that control various processings to be executed in the substrate processing apparatus 1. The control unit 90 causes the CPU 91 to execute the programs stored in the storage medium 92 so as to control the operations of the substrate processing apparatus 1.

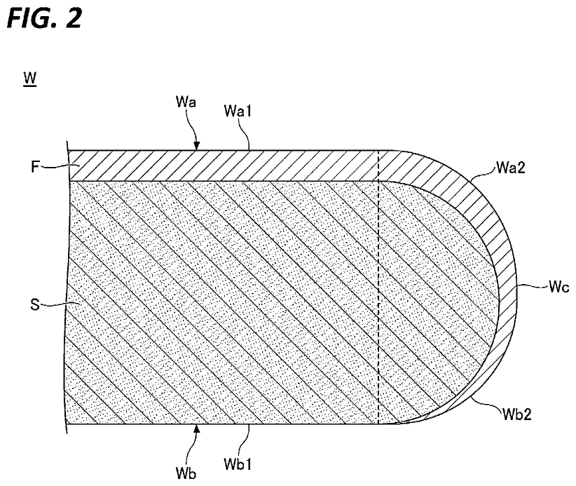

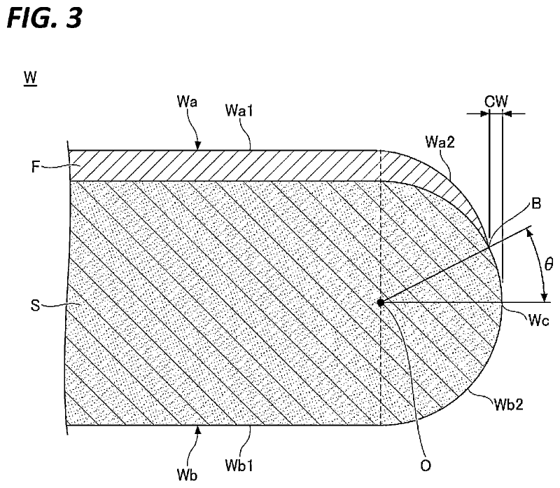

The substrate processing apparatus 1 removes the peripheral portion of a film F formed on an upper surface Wa of the substrate W (see FIG. 2 and FIG. 3). Also, in FIG. 2 and FIG. 3, the ratio of the thickness of the film F to the thickness of a base substrate S is displayed larger than it really is. The thickness of the film F is actually thin, and the shape of the base substrate S determines the shape of the substrate W.

The substrate W has a substrate upper surface Wa, a substrate lower surface Wb, and a substrate periphery Wc. The substrate upper surface Wa is an upward surface, and has a horizontal surface Wa1, and a bevel surface Wa2 formed outside the horizontal surface Wa1. The substrate lower surface Wb is a downward surface, and has a horizontal surface Wb1, and a bevel surface Wb2 formed outside the horizontal surface Wb1. The bevel surfaces Wa2 and Wb2 are so-called R surfaces, but may be so-called C surfaces. The substrate W may have a vertical surface (not illustrated) on the substrate periphery Wc.

The substrate W includes the base substrate S such as a silicon wafer, and the film F formed on the base substrate S. The base substrate S is not limited to a silicon wafer, and may be a compound semiconductor wafer or a glass substrate. The film F is, for example, a titanium nitride film, an aluminum film, a tungsten film, a silicon nitride film, a silicon oxide film, a polysilicon film, or a thermal oxide film. The film F may be formed on both the upper and lower surfaces of the base substrate S.

A plurality of films may be stacked on the base substrate S. For example, a silicon oxide film and a titanium nitride film may be formed in this order. Also, a silicon oxide film, a polysilicon film, and a tungsten film may be formed in this order. When the films are stacked, the film F to be removed may include an upper layer film, and may not include a lower layer film.

For example, when a silicon oxide film and a titanium nitride film are formed in this order, the film F to be removed may include the titanium nitride film in the upper layer, and may not include the silicon oxide film in the lower layer. Also, when a silicon oxide film, a polysilicon film, and a tungsten film are formed in this order, the film F to be removed may include the tungsten film in the upper layer, and may not include the polysilicon film and the silicon oxide film in the lower layers.

Also, the film F to be removed may be a resist film, and is not particularly limited.

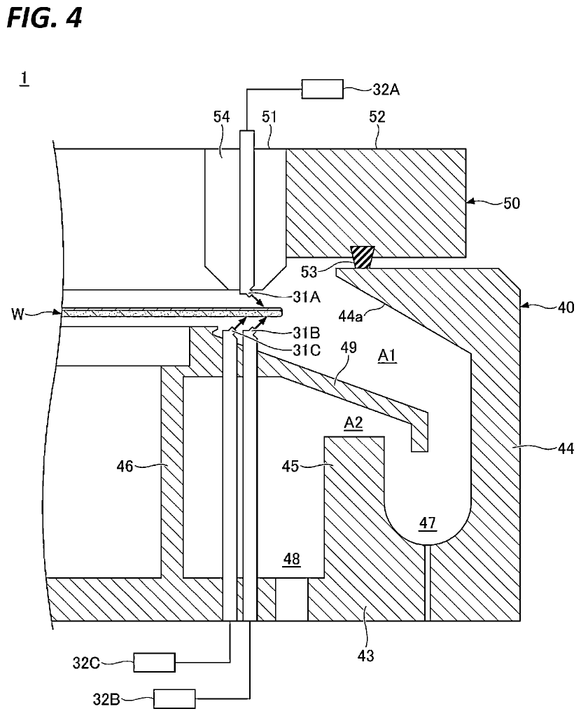

An example of a main part of the substrate processing apparatus 1 will be described with reference to FIG. 4. The cup 40 has a horizontal bottom wall 43, an outer wall 44 upwardly extending from the periphery of the bottom wall 43, a separation wall 45 disposed inside the outer wall 44, and an inner wall 46 disposed inside the separation wall 45. The outer wall 44, the separation wall 45, and the inner wall 46 are concentrically arranged. A recess 47 that collects liquid is formed between the outer wall 44 and the separation wall 45. The liquid collected in the recess 47 is discharged to the outside of the substrate processing apparatus 1 through the drain pipe 41 (see FIG. 1). Also, a recess 48 that collects gas is formed between the separation wall 45 and the inner wall 46. The gas collected in the recess 48 is discharged to the outside of the substrate processing apparatus 1 through the exhaust pipe 42 (see FIG. 1). The separation wall 45 separates the outer recess 47 from the inner recess 48 so as to separate the liquid from the gas.

The outer wall 44 of the cup 40 has a slope 44a that receives liquid scattering from the periphery of the substrate W. The slope 44a is inclined downwards and outwards in the radial direction of the substrate W. A passage A1 for both the liquid and the gas is formed between the slope 44a of the outer wall 44 and the upper surface of a guide wall 49. Also, a passage A2 for the gas is formed between the lower surface of the guide wall 49 and the upper surface of the separation wall 45. The guide wall 49 is inclined downwards from the upper end of the inner wall 46 toward the outside in the radial direction. The liquid passes through the passage A1, and is collected in the outer recess 47. The gas passes through the passages A1 and A2 and is collected in the inner recess 48.

The substrate processing apparatus 1 includes a cover 50. The cover 50 is vertically movably disposed above the substrate W held by the substrate rotating unit 20. The cover 50 is a ring-shaped member. An annular gap is formed between the cover 50 and the substrate W, and a strong airflow is formed in the gap. The airflow flows outwards in the radial direction of the substrate W, above the substrate W. The formation of the airflow may suppress the attachment of mist to the substrate upper surface Wa.

The cover 50 includes an inner cylinder 51 facing the periphery of the substrate upper surface Wa, an outer cylinder 52 disposed outside the inner cylinder 51, and a seal portion 53 that seals a gap between the outer cylinder 52 and the outer wall 44 of the cup 40. The inner cylinder 51 has a circular opening when viewed from above. The diameter of the opening is smaller than the diameter of the substrate W. A gap is formed between the inner cylinder 51 and the periphery of the substrate upper surface Wa. The inner cylinder 51 protrudes downward further than the outer cylinder 52 so that the gap becomes smaller, and furthermore, a strong airflow is formed in the gap.

A cutout 54 is formed on the inner edge of the cover 50, and a first nozzle 31A to be described below is disposed in the cutout 54. The first nozzle 31A is disposed so as to be movable in the radial direction of the substrate W.

The substrate processing apparatus 1 includes the first nozzle 31A. The first nozzle 31A is connected to a first processing liquid supply mechanism 32A. The first processing liquid supply mechanism 32A includes an opening/closing valve, a flow meter, and a flow rate controller. The first processing liquid supply mechanism 32A supplies a first processing liquid to the first nozzle 31A. The first nozzle 31A supplies the first processing liquid toward the substrate W from above the substrate W held by the substrate rotating unit 20. The first processing liquid inhibits the film F from being removed by a second processing liquid to be described below. The first processing liquid is, for example, DIW (deionized water).

The first processing liquid is supplied to the substrate upper surface Wa [specifically, the horizontal surface Wa1 of the substrate upper surface Wa], and then flows outwards in the radial direction of the substrate W by a centrifugal force. The first processing liquid suppresses the second processing liquid from flowing from the substrate lower surface Wb to the substrate upper surface Wa via the substrate periphery Wc. Also, the first processing liquid dilutes the second processing liquid. The first processing liquid is not limited to DIW as long as it can inhibit the film F from being removed by the second processing liquid.

The first nozzle 31A may eject the first processing liquid obliquely downwards and outwards in the radial direction of the substrate W. Accordingly, the first processing liquid may be supplied to the substrate upper surface Wa without going against a centrifugal force, and the first processing liquid may be suppressed from scattering due to the impact when the first processing liquid collides with the substrate upper surface Wa. Also, although not illustrated, the first processing liquid may be ejected by the first nozzle 31A, obliquely downwards and outwards in the radial direction of the substrate W and toward the rotation direction of the substrate W.

Also, the substrate processing apparatus 1 includes a second nozzle 31B. The second nozzle 31B is connected to a second processing liquid supply mechanism 32B. The second processing liquid supply mechanism 32B includes an opening/closing valve, a flow meter, and a flow rate controller. The second processing liquid supply mechanism 32B supplies a second processing liquid to the second nozzle 31B. The second nozzle 31B supplies the second processing liquid toward the substrate W from below the substrate W held by the substrate rotating unit 20. The second processing liquid removes the film F. The second processing liquid is selected according to the type of the film F to be removed. For example, when the film F is a tungsten film or a titanium nitride film, the second processing liquid may be hydrogen peroxide water.

The second processing liquid is supplied to the substrate lower surface Wb [specifically, the horizontal surface Wb1 of the substrate lower surface Wb], and then flows outwards in the radial direction of the substrate W by a centrifugal force. The second processing liquid flows from the substrate lower surface Wb to the substrate upper surface Wa via the substrate periphery Wc, and removes the peripheral portion of the film F. The second processing liquid is, for example, an etching liquid or a developer, and is not particularly limited.

The second nozzle 31B may eject the second processing liquid obliquely upwards and outwards in the radial direction of the substrate W. Accordingly, the second processing liquid may be supplied to the substrate lower surface Wb without going against a centrifugal force, and the second processing liquid may be suppressed from scattering due to the impact when the second processing liquid collides with the substrate lower surface Wb. Also, although not illustrated, the second processing liquid may be ejected by the second nozzle 31B, obliquely upwards and outwards in the radial direction of the substrate W and toward the rotation direction of the substrate W.

The substrate processing apparatus 1 may include a third nozzle 31C. The third nozzle 31C is connected to a third processing liquid supply mechanism 32C. The third processing liquid supply mechanism 32C includes an opening/closing valve, a flow meter, and a flow rate controller. The third processing liquid supply mechanism 32C supplies the third processing liquid to the third nozzle 31C. The third nozzle 31C supplies the third processing liquid toward the substrate W from below the substrate W held by the substrate rotating unit 20. Subsequent to the second processing liquid, the third processing liquid is supplied to the substrate W, and washes away the second processing liquid remaining on the substrate W. The third processing liquid is not particularly limited, but is, for example, DIW.

The third processing liquid is supplied to the substrate lower surface Wb [specifically, the horizontal surface Wb1 of the substrate lower surface Wb], and then flows outwards in the radial direction of the substrate W by a centrifugal force. The third processing liquid flows from the substrate lower surface Wb to the substrate upper surface Wa via the substrate periphery Wc, and is mixed with the first processing liquid. It is desirable that the third processing liquid is the same type as the first processing liquid.

The third nozzle 31C may eject the third processing liquid obliquely upwards and outwards in the radial direction of the substrate W. Accordingly, the third processing liquid may be supplied to the substrate lower surface Wb without going against a centrifugal force, and the third processing liquid may be suppressed from scattering due to the impact when the third processing liquid collides with the substrate lower surface Wb. Also, although not illustrated, the third processing liquid may be ejected by the third nozzle 31C obliquely upwards and outwards in the radial direction of the substrate W and toward the rotation direction of the substrate W.

The third nozzle 31C may be arranged inside in the radial direction of the substrate W compared to the second nozzle 31B. The third processing liquid may be supplied to the whole area to which the second processing liquid is supplied, thereby reducing the residue of the second processing liquid.

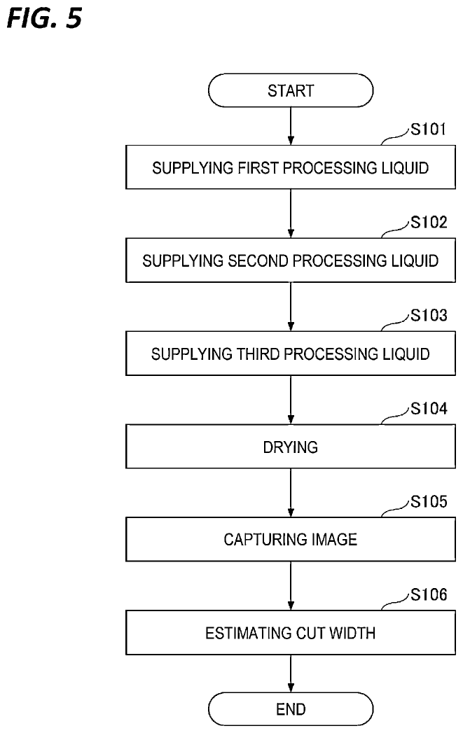

A substrate processing method according to one embodiment will be described with reference to FIG. 5 to FIG. 12. The substrate processing method includes, for example, steps S101 to S106 as illustrated in FIG. 5. The steps S101 to S106 are performed under the control by the control unit 90. The processing from the step S101 is started when the substrate W is carried into the processing container 10 by a transport device (not illustrated), and the substrate rotating unit 20 holds the substrate W horizontally.

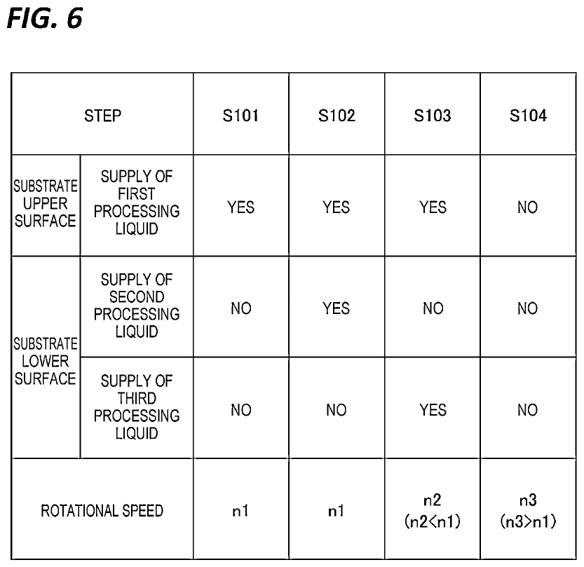

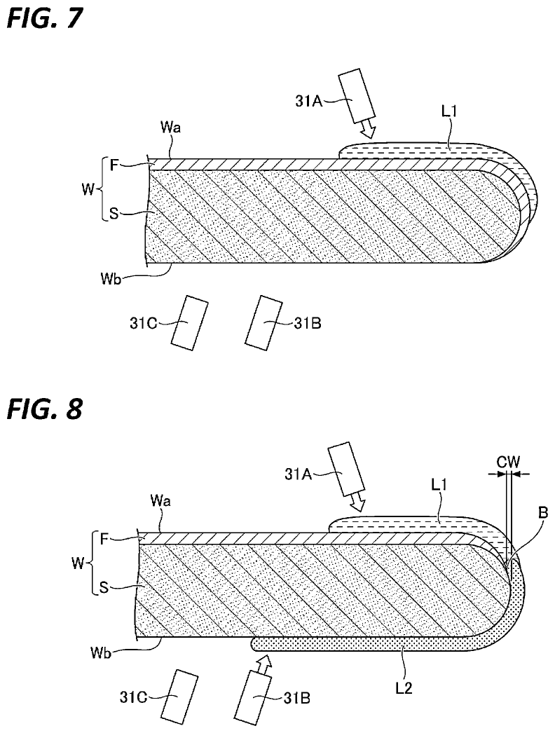

The step S101 includes supplying a first processing liquid L1 by the first nozzle 31A in a state where the substrate W is rotated by the substrate rotating unit 20 at a first rotational speed n1 as illustrated in FIG. 6 and FIG. 7. The first processing liquid L1 is supplied to the substrate upper surface Wa (specifically, the horizontal surface Wa1 of the substrate upper surface Wa), and then flows outwards in the radial direction of the substrate W. The first processing liquid L1 may flow to the substrate lower surface Wb beyond the substrate periphery Wc. In the step S101, a second processing liquid L2 and a third processing liquid L3 are not supplied to the substrate W.

In the step S102, as illustrated in FIG. 6 and FIG. 8, the second processing liquid L2 is supplied by the second nozzle 31B in a state where the substrate W is rotated by the substrate rotating unit 20 at the first rotational speed n1. The second processing liquid L2 is supplied to the substrate lower surface Wb, and then flows from the substrate lower surface Wb to the substrate upper surface Wa via the substrate periphery Wc, and removes the peripheral portion of the film F.

In the step S102, not only the second processing liquid L2, but also the first processing liquid L1 is supplied to the substrate W. The first processing liquid L1 suppresses inflowing of the second processing liquid L2 and dilutes the second processing liquid L2, thereby inhibiting the film F from being removed by the second processing liquid L2. As a result, a boundary B between a covered portion and an exposed portion is formed on the substrate upper surface Wa. The covered portion is a portion where the film F remains, and the exposed portion is a portion from which the film F is removed. The exposed portion is formed on the radial outside of the covered portion. The width CW of the exposed portion when viewed from above is also called a cut width CW.

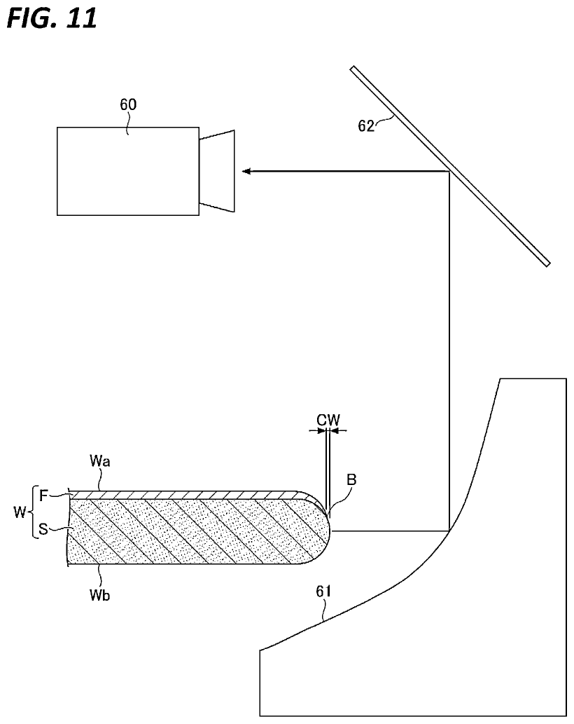

As described above, the first processing liquid L1 suppresses inflowing of the second processing liquid L2 and dilutes the second processing liquid L2, thereby inhibiting the film F from being removed by the second processing liquid L2. By supplying the first processing liquid L1, the cut width CW can be made smaller than in the case where the first processing liquid L1 is not supplied (see FIG. 10).

By reducing the cut width CW, the effective area of the horizontal surface Wa1 of the substrate upper surface Wa (for example, an area where a chip is formed) may be expanded. Also, by reducing the cut width CW, a wide range of the horizontal surface Wa1 of the substrate upper surface Wa may be protected by the covered portion in subsequent etching processing, so that the occurrence of defects such as voids may be suppressed.

As described above, the second processing liquid L2 is supplied to the substrate lower surface Wb, and then flows from the substrate lower surface Wb to the substrate upper surface Wa via the substrate periphery Wc. Unlike in a case where the second processing liquid L2 is directly supplied to the substrate upper surface Wa, the cut width CW may be controlled at the first rotational speed n1. The higher the first rotational speed n1, the larger the centrifugal force, and then the inflowing of the second processing liquid L2 is suppressed, thereby reducing the cut width CW (see FIG. 10).

Also, when the second processing liquid L2 is directly supplied to the substrate upper surface Wa as in Patent Document 1, the cut width CW is determined at the supply position. If an attempt is made to control the cut width CW at the supply position of the second processing liquid L2, the shape of the boundary B is likely to be a jagged circle rather than a neat circle when viewed from above. If the cut width CW is small, the fluctuation of the cut width CW is easily noticeable. Also, if an attempt is made to directly supply the second processing liquid L2 to the bevel surface Wa2 of the substrate upper surface Wa, the supply position will fluctuate in any way, and then the shape of the boundary B is likely to be a jagged circle when viewed from above.

According to the present embodiment, as described above, after being supplied to the substrate lower surface Wb, the second processing liquid L2 flows from the substrate lower surface Wb to the substrate upper surface Wa via the substrate periphery Wc. Unlike in a case where the second processing liquid L2 is directly supplied to the substrate upper surface Wa, the cut width CW may be controlled at the first rotational speed n1. Furthermore, the inflowing of the second processing liquid L2 may be stabilized by the first processing liquid L1. Therefore, the shape of the boundary B may be made closer to a neat circle when viewed from above. That is, the cut width CW may be stably reduced.

According to the present embodiment, since the cut width CW can be stably reduced, it is also possible to remove the peripheral portion of the film F such that the boundary B stays on the bevel surface Wa2. When the peripheral portion of the film F is removed such that the boundary B stays on the bevel surface Wa2, the control unit 90 only needs to set the first rotational speed n1 higher than when the peripheral portion of the film F is removed such that the boundary B may reach the horizontal surface Wa1 beyond the bevel surface Wa2. It is desirable to set the first rotational speed n1 at 800 rpm to 2400 rpm.

As illustrated in FIG. 6 to FIG. 8, after starting the supply of the first processing liquid L1 by the first nozzle 31A, the control unit 90 performs a control for starting the supply of the second processing liquid L2 by the second nozzle 31B. By starting the supply of the first processing liquid L1 prior to the supply of the second processing liquid L2, it is possible to stabilize the inflowing of the second processing liquid L2. It is desirable that after the first processing liquid L1 reaches the substrate periphery Wc, the control unit 90 starts the supply of the second processing liquid L2.

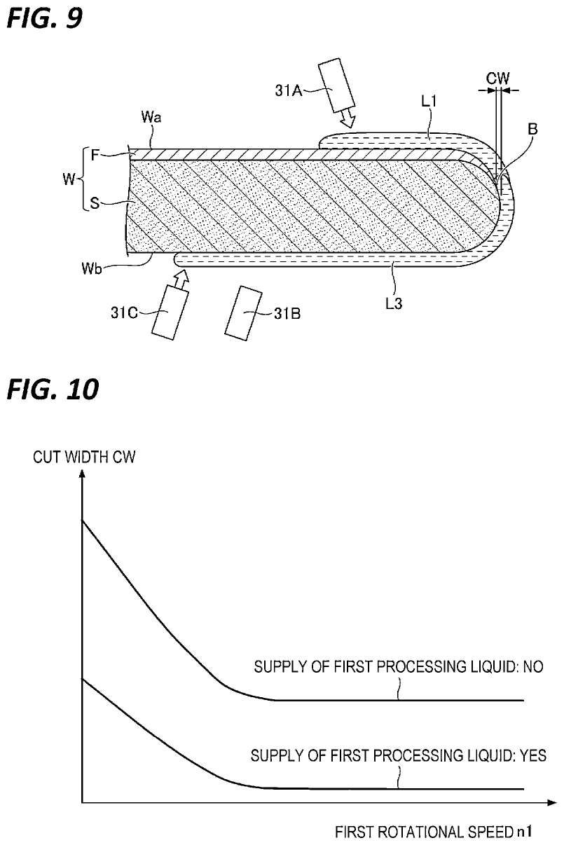

As illustrated in FIG. 6 and FIG. 9, the step S103 includes supplying the third processing liquid L3 by the third nozzle 31C in a state where the substrate W is rotated by the substrate rotating unit 20 at a second rotational speed n2 lower than the first rotational speed n1. The step S103 is performed after the control for removing the peripheral portion of the film F is ended by stopping the supply of the second processing liquid L2. The second processing liquid L2 remaining on the substrate W may be washed away by the third processing liquid L3. By setting the second rotational speed n2 lower than the first rotational speed n1, the generation of mist may be suppressed, and furthermore, the generation of particles may be suppressed. The second rotational speed n2 is, for example, 400 rpm to 800 rpm.

During the steps S101 to S103, it is desirable that the position of the first nozzle 31A is fixed to suppress the generation of mist.

As illustrated in FIG. 6, the step S104 includes drying the substrate W by rotating the substrate W by the substrate rotating unit 20 at a third rotational speed n3 higher than the first rotational speed n1. The step S104 is performed after the supply of the first processing liquid L1 and the third processing liquid L3 is stopped. The higher the third rotational speed n3, the stronger the centrifugal force, and then the substrate W is easily dried. The third rotational speed n3 is, for example, 2200 rpm to 3000 rpm.

As illustrated in FIG. 11, the step S105 includes capturing an image of the periphery of the substrate W from the side view, by an imaging unit 60. The processing from the step S105 may be performed before or after the substrate W is carried out of the processing container 10. That is, the imaging unit 60 may be provided inside or outside the processing container 10.

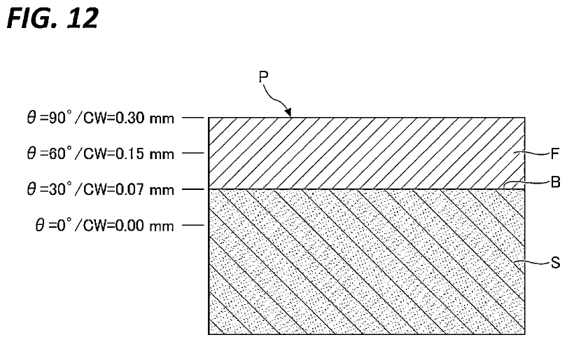

The imaging unit 60 is a camera. The camera may be either a color camera or a monochrome camera. The imaging unit 60 captures an image P of the periphery of the substrate W from the side view (see FIG. 12), via, for example, a curved mirror 61 and a planar mirror 62. The curved mirror 61 is disposed on the side of the periphery of the substrate W, and the planar mirror 62 is disposed above the curved mirror 61. Also, the curved mirror 61 and the planar mirror 62 may not be present, and the imaging unit 60 may be disposed on the side of the periphery of the substrate W.

The imaging unit 60 may capture an image of the periphery of the substrate W from the top view, but as illustrated in FIG. 12, it is desirable to capture the image P of the periphery of the substrate W from the side view. When the peripheral portion of the film F is removed such that the boundary B stays on the bevel surface Wa2, the boundary B is easier to detect in the image P viewed from the side than in the image viewed from above.

In the step S106, the image P is processed so that the boundary B is detected and the cut width CW is estimated. The relationship between the coordinates of the boundary B in the image P and the cut width CW is stored in advance for each shape of the bevel surface Wa2. After detecting the coordinates of the boundary B in the image P, the control unit 90 estimates the cut width CW by referring to the previously stored information.

Also, the relationship between the coordinates of the boundary B in the image P, the angle θ illustrated in FIG. 3, and the cut width CW may be stored in advance. As illustrated in FIG. 3, the angle θ is an angle formed by a horizontal line and a straight line connecting the boundary B to an intersection O. The intersection O is between a vertical line passing through the upper end of the bevel surface Wa2 and a horizontal line passing through the lower end of the bevel surface Wa2. After detecting the coordinates of the boundary B in the image P, the control unit 90 may estimate the angle θ and the cut width CW by referring to the previously stored information.

The control unit 90 may perform a control for displaying the image P on an image display device. The displayed image P may include a scale indicating the size of at least one of the cut width CW and the angle θ as illustrated in FIG. 12. The vertical coordinate of the image P may be proportional to, for example, the angle θ. By looking at the image P displayed on the image display device, the user may detect the boundary B, and estimate the cut width CW.

Regarding the above embodiment, the following supplementary notes are disclosed.

[Appendix 1] A substrate processing apparatus that removes a peripheral portion of a film formed on an upper surface of a substrate, the substrate processing apparatus including:
a substrate rotating unit that horizontally holds and rotates the substrate; a first nozzle that supplies a first processing liquid toward the substrate from above the substrate held by the substrate rotating unit, thereby hindering removal of the film;
a second nozzle that supplies a second processing liquid toward the substrate from below the substrate held by the substrate rotating unit, thereby removing the film; and
a control unit that controls rotation of the substrate, supply of the first processing liquid, and supply of the second processing liquid,
in which the control unit controls the first nozzle and the second nozzle to supply the first processing liquid and the second processing liquid, respectively, while rotating the substrate by the substrate rotating unit at a first rotational speed, thereby removing the peripheral portion of the film.

[Appendix 2] The substrate processing apparatus described in Appendix 1, in which the upper surface of the substrate held by the substrate rotating unit has a horizontal surface, and a bevel surface formed outside the horizontal surface, and the control unit performs a control for removing the peripheral portion of the film such that a boundary between a covered portion where the film remains and an exposed portion from which the film is removed stays on the bevel surface.

[Appendix 3] The substrate processing apparatus described in Appendix 2, in which when the peripheral portion of the film is removed such that the boundary stays on the bevel surface, the control unit performs a control for setting the first rotational speed higher than when the peripheral portion of the film is removed such that the boundary reaches the horizontal surface beyond the bevel surface.

[Appendix 4] The substrate processing apparatus described in Appendix 2 or 3, further including:
an imaging unit that captures an image of a periphery of the substrate from the side view,
in which the control unit processes the image, thereby detecting the boundary, and estimating a width of the exposed portion from the top view.

[Appendix 5] The substrate processing apparatus described in any one of Appendices 1 to 4, in which the first nozzle ejects the first processing liquid obliquely downwards and outwards in a radial direction of the substrate,
the second nozzle ejects the second processing liquid obliquely upwards and outwards in the radial direction of the substrate, and
after starting the supply of the first processing liquid by the first nozzle, the control unit performs a control for starting the supply of the second processing liquid by the second nozzle.

[Appendix 6] The substrate processing apparatus described in any one of Appendices 1 to 5, further including:
a third nozzle that supplies a third processing liquid toward the substrate from below the substrate held by the substrate rotating unit,
in which after the control for removing the peripheral portion of the film is ended by stopping the supply of the second processing liquid by the second nozzle, the control unit performs a control for supplying the third processing liquid by the third nozzle in a state where the substrate is rotated by the substrate rotating unit at a second rotational speed lower than the first rotational speed.

[Appendix 7]A substrate processing method including:
removing a peripheral portion of a film formed on an upper surface of a substrate,
in which the removing the peripheral portion of the film is performed by supplying a first processing liquid toward the substrate from a first nozzle above the substrate, and supplying a second processing liquid toward the substrate from a second nozzle below the substrate in a state where the substrate is rotated at a first rotational speed, the first processing liquid inhibiting removal of the film, and the second processing liquid removing the film.

[Appendix 8] The substrate processing method described in Appendix 7, in which the upper surface of the substrate rotated at the first rotational speed has a horizontal surface, and a bevel surface formed outside the horizontal surface, and
the substrate processing method includes removing the peripheral portion of the film such that a boundary between a covered portion where the film remains and an exposed portion from which the film is removed stays on the bevel surface.

[Appendix 9] The substrate processing method described in Appendix 8, further including:
when the peripheral portion of the film is removed such that the boundary stays on the bevel surface, setting the first rotational speed higher than when the peripheral portion of the film is removed such that the boundary reaches the horizontal surface beyond the bevel surface.

[Appendix 10] The substrate processing method described in Appendix 8 or 9, further including:
capturing an image of a periphery of the substrate in a side view; and
processing the image, thereby detecting the boundary, and estimating a width of the exposed portion in a top view.

[Appendix 11] The substrate processing method described in any one of Appendices 7 to 10, in which the first nozzle ejects the first processing liquid obliquely downwards and outwards in a radial direction of the substrate,
the second nozzle ejects the second processing liquid obliquely upwards and outwards in the radial direction of the substrate, and
after starting supply of the first processing liquid by the first nozzle, the second nozzle starts ejecting the second processing liquid.

[Appendix 12] The substrate processing method described in any one of Appendices 7 to 11, further including:
after removal of the peripheral portion of the film is ended by stopping supply of the second processing liquid, supplying a third processing liquid toward the substrate from a third nozzle below the substrate while the substrate is rotated at a second rotational speed lower than the first rotational speed.

So far, descriptions have been made on a substrate processing apparatus and a substrate processing method according to an embodiment of the present disclosure, but the present disclosure is not limited to the above embodiment, etc. Within the scope described in the claims, various changes, modifications, substitutions, additions, deletions, and combinations are possible. These also naturally fall within the technical scope of the present disclosure.

This application claims priority based on Japanese Patent Application No. 2022-068333 filed with the Japan Patent Office on Apr. 18, 2022, and the entire contents of Japanese Patent Application No. 2022-068333 are incorporated in this application.

### DESCRIPTION OF SYMBOLS

1: Substrate processing apparatus
20: Substrate rotating unit
31A: First nozzle
31B: Second nozzle
90: Control unit
W: Substrate
F: Film

1. A substrate processing apparatus comprising:
a substrate rotator configured to horizontally hold and rotate a substrate;
a first nozzle configured to supply a first processing liquid toward the substrate held by the substrate rotator, from above;
a second nozzle configured to supply a second processing liquid toward the substrate held by the substrate rotator, from below; and
a controller configured to control rotation of the substrate, supply of the first processing liquid, and supply of the second processing liquid,
wherein the controller controls the first nozzle and the second nozzle to supply the first processing liquid and the second processing liquid, respectively, while rotating the substrate by the substrate rotator at a first rotational speed, thereby removing a peripheral portion of a film formed on an upper surface of the substrate.

2. The substrate processing apparatus according to claim 1, wherein the upper surface of the substrate held by the substrate rotator has a horizontal surface, and a bevel surface formed outside the horizontal surface, and
the controller controls the removing the peripheral portion of the film such that a boundary between a covered portion where the film remains and an exposed portion from which the film is removed stays on the bevel surface.

3. The substrate processing apparatus according to claim 2, wherein when the peripheral portion of the film is removed such that the boundary stays on the bevel surface, the controller sets the first rotational speed to be higher than when the peripheral portion of the film is removed such that the boundary reaches the horizontal surface beyond the bevel surface.

4. The substrate processing apparatus according to claim 2, further comprising:
a camera configured to capture an image of the peripheral portion of the substrate in a side view,
wherein the controller processes the image, thereby detecting the boundary, and estimating a width of the exposed portion in a top view.

5. The substrate processing apparatus according to claim 1, wherein the first nozzle ejects the first processing liquid obliquely downwards and outwards in a radial direction of the substrate,
the second nozzle ejects the second processing liquid obliquely upwards and outwards in the radial direction of the substrate, and
after starting the supply of the first processing liquid by the first nozzle, the controller starts the supply of the second processing liquid by the second nozzle.

6. The substrate processing apparatus according to claim 1, further comprising:
a third nozzle configured to supply a third processing liquid toward the substrate held by the substrate rotator, from below,
wherein after the removing the peripheral portion of the film is ended by stopping the supply of the second processing liquid by the second nozzle, the controller controls the third nozzle to supply the third processing liquid while rotating the substrate by the substrate rotator at a second rotational speed lower than the first rotational speed.

7. A substrate processing method comprising:
rotating a substrate at a first rotation speed;
supplying a first processing liquid for hindering removal of the film, toward the substrate from a first nozzle above the substrate, and
supplying a second processing liquid for removing the film, toward the substrate from a second nozzle below the substrate, thereby removing a peripheral portion of a film formed on an upper surface of the substrate.

8. The substrate processing method according to claim 7, wherein the upper surface of the substrate rotated at the first rotational speed has a horizontal surface, and a bevel surface formed outside the horizontal surface, and
the peripheral portion of the film is removed such that a boundary between a covered portion where the film remains and an exposed portion from which the film is removed stays on the bevel surface.

9. The substrate processing method according to claim 8, further comprising:
when the peripheral portion of the film is removed such that the boundary stays on the bevel surface, setting the first rotational speed to be higher than when the peripheral portion of the film is removed such that the boundary reaches the horizontal surface beyond the bevel surface.

10. The substrate processing method according to claim 8, further comprising:
capturing an image of the peripheral portion of the substrate in a side view; and
processing the image, thereby detecting the boundary, and estimating a width of the exposed portion in a top view.

11. The substrate processing method according to claim 7, wherein the first nozzle ejects the first processing liquid obliquely downwards and outwards in a radial direction of the substrate,
the second nozzle ejects the second processing liquid obliquely upwards and outwards in the radial direction of the substrate, and
after the first nozzle starts ejecting the first processing liquid, the second nozzle starts ejecting the second processing liquid.

12. The substrate processing method according to claim 7, further comprising:
after the removing the peripheral portion of the film is ended by stopping the supplying the second processing liquid, supplying a third processing liquid toward the substrate from a third nozzle below the substrate while the substrate is rotated at a second rotational speed lower than the first rotational speed.
